(19) United States
(12) Patent Application Publication
(10) Pub. No.: US 2007/0291459 A1
(43) Pub. Date: Dec. 20, 2007

(54) CIRCUIT BOARD FOR REDUCING ELECTROMAGNETIC INTERFERENCE

(75) Inventors: SHOU-KUO HSU, Tu-Cheng (TW); YU-CHANG PAI, Tu-Cheng (TW); CHUN-JEN CHEN, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/558,472

(22) Filed: Nov. 10, 2006

(30) Foreign Application Priority Data
Jun. 16, 2006 (CN) 200610061178.2

(51) Int. Cl. H05K 1/11; H05K 1/14

(52) U.S. Cl. 361/794

(57) ABSTRACT

An exemplary circuit board includes a power plane with a first metal plate, a ground plane with a second metal plate, a channel etched in one of the metal plates to define an isolated area therein, and a coupling circuit. A gap is formed between the isolated area and other area of the one of the metal plates. The coupling circuit is electronically connected between the first and the second metal plates in the isolated area for reducing a resonance frequency caused by the channel. The circuit board can reduce electromagnetic interference generated therein.

### BACKGROUND OF THE INVENTION

1. Field of the Invention

The present invention relates to circuit boards, and particularly to a circuit board reducing electromagnetic interference generated therein.

2. Description of Related Art

It is well known that, in a multilayer PCB, a ground plane is used to provide a reference potential in circuits and a power plane is used to provide operating power to integrated circuits (ICs) and large scale integrated circuits (LSIs). When an electronic circuit on a PCB is operated, a voltage is generated and a current flows, the variations in voltages between the power plane and ground plane cause emission of unwanted electromagnetic waves such as ground bounce noise. To reduce the emission of the electromagnetic interference, PCBs having various kinds of structures are introduced and various kinds of methods for designing the PCBs are available accordingly.

Referring to FIG. 3, a conventional circuit board 10 includes a power plane 12, a ground plane 13, and a base plate 11 sandwiched between the power plane 12 and the ground plane 13. The power plane 12 has a metal plate 121, and a channel 122 etched in the metal plate 121 to define a rectangular isolated area 123 therein. Two ends of the channel 122 do not meet, thereby leaving a gap 124 therebetween for communicating the isolated area 123 and the other part of the metal plate 121.

The isolated area 123 can reduce electromagnetic interference generated in the isolated area 123. The gap 124 couples the isolated area 123 and the other part of the metal plate 121 for making a voltage level of the isolated area 123 equal to a voltage level of the power plane 12.

The disadvantage of above mentioned design is the gap 124. The gap 124 causes a resonance frequency in a low-frequency band (such as 462 Mhz) and reduces the effectiveness of the isolated area 123.

What is needed, therefore, is a circuit board which can solve the above problem.

### SUMMARY OF THE INVENTION

An exemplary circuit board includes a power plane with a first metal plate, a ground plane with a second metal plate, a channel etched in one of the metal plates to define an isolated area therein, and a coupling circuit. A gap is formed between the isolated area and other area of the one of the metal plates. The coupling circuit is electronically connected between the first and the second metal plates in the isolated area for reducing a resonance frequency caused by the channel.

Other advantages and novel features will become more apparent from the following detailed description when taken in conjunction with the accompanying drawings, in which:

### BRIEF DESCRIPTION OF THE DRAWINGS

FIG. 1 is a schematic diagram of one embodiment of a circuit board in accordance with the present invention;

FIG. 2 is a graph comparing waveforms generated by the circuit board of FIG.1, and two conventional circuit boards; and

FIG. 3 is a schematic diagram of a conventional circuit board.

### DETAILED DESCRIPTION OF THE INVENTION

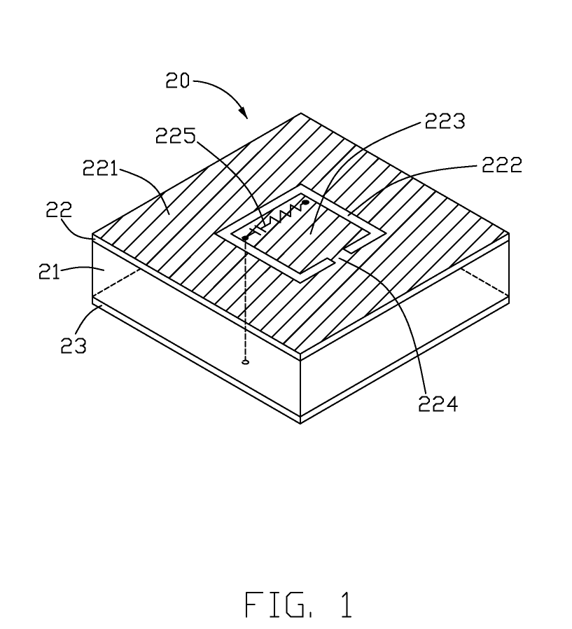

Referring to FIG. 1, a circuit board 20 in accordance with a preferred embodiment of the present invention includes a power plane 22, a ground plane 23, a base plate 21 sandwiched between the power plane 22 and the ground plane 23, an isolated area 223, and a coupling circuit 225.

The power plane 22 has a first metal plate 221, and a channel 222 etched in the metal plate 221 to define an isolated area 223 substantially surrouned by the channel 222. Two ends of the channel 222 do not meet, thereby leaving a gap 224 therebetween for communicating the isolated area 223 and the other area of the metal plate 221. The ground plane 23 has a second metal plate. Another isolated area similar to the isolated area 223 can be defined in the second metal plate as well in the same way.

The coupling circuit 225 is defined in the isolated area 223 and includes a resistor and a capacitor connected in series in the isolated area 223. The coupling circuit 225 is electrically connected between the first metal plate 221 and the second metal plate for reducing a resonance frequency caused by the gap 224.

In the above-described circuit board of the preferred embodiment of the present invention, the resonance frequency caused by the gap 224 is 462 MHz, therefore a resistance of the resistor is 6 ohms, and a capacitance of the capacitor is 56 pF.

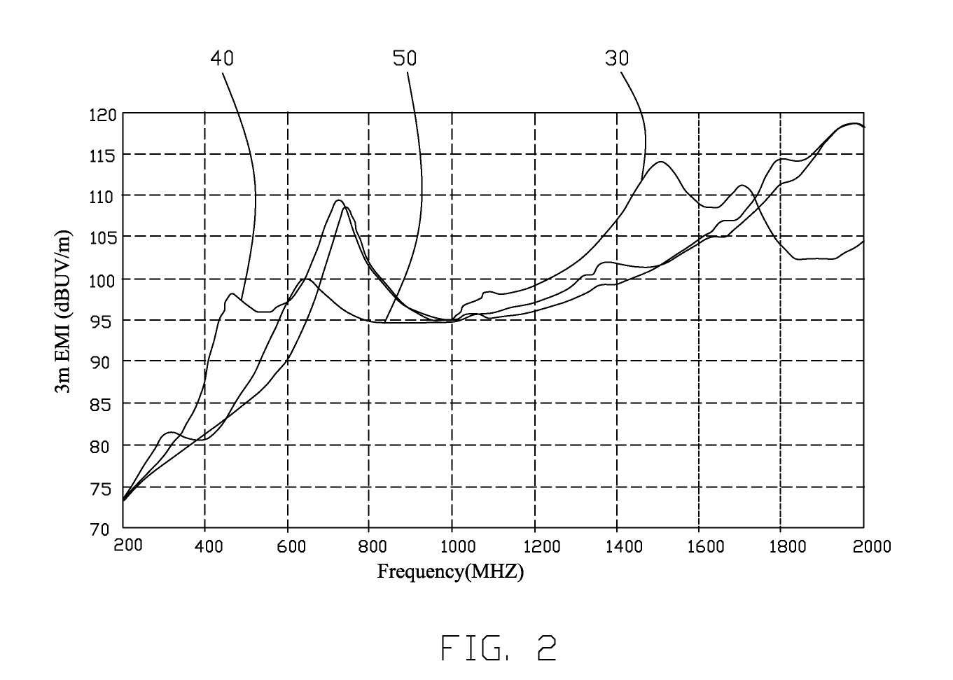

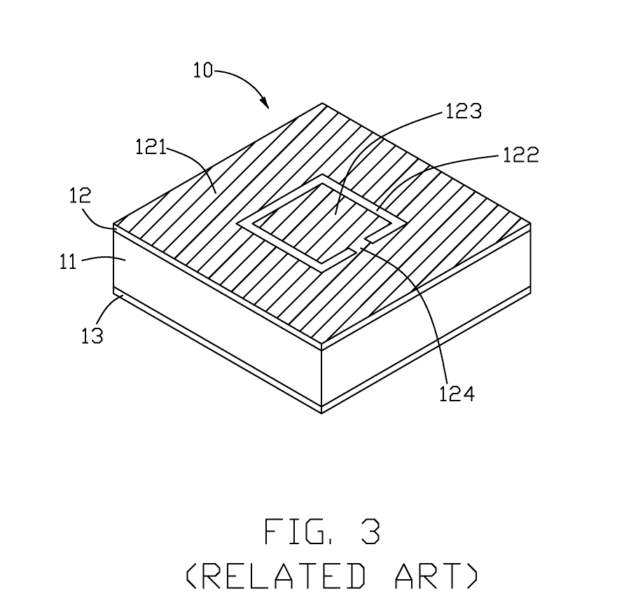

Referring to FIG. 2, curve 30 is a frequency waveform obtained using a circuit board without an isolated area, curve 40 is a frequency waveform obtained using the conventional circuit board 10 of FIG. 3, with the isolated area 123, and curve 50 is a frequency waveform obtained using the circuit board 20 of the present invention with the isolated area 223 and the coupling circuit 225. Comparing curve 40 with curve 30, the isolated area 123 reduces electromagnetic interference generated therein, and produces a new resonance frequency in 462 MHz. Referring to curve 50, the isolated area 223 reduces electromagnetic interference generated therein, and further, the coupling circuit 225 reduces EMI at the resonance frequency of 462 MHz.

The isolated area 223 of the circuit board 20 reduces electromagnetic interference generated therein, and the coupling circuit 225 reduces the resonance frequency caused by the gap 224. Therefore, the circuit board 20 can efficiently reduce electromagnetic interference generated therein.

In the above-described circuit board of the preferred embodiment of the present invention, the isolated area 223 is square shaped. A shape of the isolated area 223 can be selected from a group of triangle, rhombus, and rectangle.

In the above-described circuit board of the preferred embodiment of the present invention, the base plate 21 is a PCB. The base plate 21 can be a semiconductor substrate as well.

The foregoing description of the exemplary embodiments of the invention has been presented only for the purposes of illustration and description and is not intended to be exhaustive or to limit the invention to the precise forms disclosed. Many modifications and variations are possible in light of the above teaching. The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A circuit board comprising:
a power plane having a first metal plate;
a ground plane having a second metal plate;
a channel etched in one of the metal plate to define an isolated area substantially surrounded by the channel, leaving a gap between two ends of the channel for communicating the isolated area and other area of said one of the metal plate; and
a coupling circuit electronically connected between the first and the second metal plates in the isolated area .

2. The circuit board as claimed in claim 1, wherein the coupling circuit comprises a resistor and a capacitor connected in series.

3. The circuit board as claimed in claim 1, wherein the isolated area is square shaped.

4. The circuit board as claimed in claim 1, wherein a shape of the isolated area is selected from a group of triangle, rhombus, and rectangle.

5. A circuit board comprising:
a base plate having metal plates on two opposite sides thereof;
a channel etched in one of the metal plates to define a rectangular isolated area therein, leaving a gap between two ends of the channel for communicating the isolated area and the one of the metal plates; and
a coupling circuit electronically connected between the metal plates in the isolated area.

6. The circuit board as claimed in claim 5, wherein the base plate is a printed circuit board.

7. The circuit board as claimed in claim 5, wherein the base plate is a semiconductor substrate.

8. The circuit board as claimed in claim 5, wherein the coupling circuit comprises a resistor and a capacitor connected in series.

9. A circuit board comprising:
a power plane having a first metal plate;
a ground plane having a second metal plate;
a channel etched in one of the metal plate to define an isolated area substantially surrounded by the channel except a gap between two ends of the channel for communicating the isolated area and other area of said one of the metal plate; and
a coupling circuit defined in the isolated area and electronically connected between the first and the second metal plates for reducing a resonance frequency caused by the channel.

10. The circuit board as claimed in claim 9, wherein the coupling circuit comprises a resistor and a capacitor connected in series.

11. The circuit board as claimed in claim 10, wherein a resistance of the resistor is 6 ohms, and a capacitance of the capacitor is 56 pF.
